(19) United States
(12) Patent Application Publication
(10) Pub. No.: US 2017/0170330 A1
(43) Pub. Date: Jun. 15, 2017

(54) THIN FILM TRANSISTORS (TFTS), MANUFACTURING METHODS OF TFTS, AND DISPLAY DEVICES

(71) Applicant: Shenzhen China Star Optoelectronics Technology Co., Ltd., Shenzhen, Guangdong (CN)

(72) Inventor: Wenhui LI, Shenzhen, Guangdong (CN)

(73) Assignee: Shenzhen China Star Optoelectronics Technology Co., Ltd., Shenzhen, Guangdong (CN)

(21) Appl. No.: 14/905,802

(22) PCT Filed: Jul. 31, 2015
(86) PCT No.: PCT/CN2015/085737

§ 371 Date: Jan. 16, 2016

(30) Foreign Application Priority Data
Jul. 16, 2015 (CN) 201510420701.5

(51) Int. Cl. H01L 29/786; H01L 29/51; H01L 21/425; H01L 29/24; H01L 27/12; H01L 21/02

(52) U.S. Cl. CPC H01L 29/78696; H01L 27/127; H01L 21/02565; H01L 21/02631; H01L 21/425; H01L 29/7869; H01L 29/24; H01L 29/51; H01L 29/518; H01L 27/1225

(57) ABSTRACT

The present disclosure discloses a manufacturing method of TFTs. The method includes: providing a substrate; forming a first metallic layer on the substrate, and applying a patterning process to the first metallic layer such that the first metallic layer comprises a pattern having a gate; forming a gate insulation layer on the substrate and the first metallic layer, the gate insulation layer covers a surface of the substrate and the gate; forming an oxide conductor layer orthogonally projecting on the gate on the gate insulation layer, wherein the oxide conductor layer is formed by physical vapor deposition (PVD); forming a second metallic layer on the substrate having the gate insulation layer formed thereon, patterning the second metallic layer to form a source and a drain of the TFT, wherein the source and the drain cover a portion of the oxide conductor layer.

### CROSS REFERENCE

This application claims the priority of Chinese Patent Application No. 201510420701.5, entitled “Thin film transistors (TFTs), manufacturing methods of TFTs, and display devices”, filed on Jul. 16, 2015, the disclosure of which is incorporated herein by reference in its entirety.

### FIELD OF THE INVENTION

The present invention relates to a TFT manufacturing field, and more particularly to a TFT, a manufacturing method of TFTs, and a display device.

### BACKGROUND OF THE INVENTION

The popular Oxide TFTsadopt oxide semiconductor as an active layer, and is characterized by attributes such as high mobility rate, high on-state current, better switching characteristics, and better uniformity, and thus are suitable for applications needing a fast response time and larger current, such as large-scale displays of high frequency and high definition and OLEDs. Currently, the TFT may include gate lines, a gate, a semiconductor layer, a source, a drain, a passivation layer, and at least one pixel electrode. Within the manufacturing process, the source/drain electrode layer and the oxide semiconductor film are made by metallic materials having low resistance. When the source/drain electrode layer and the oxide semiconductor film contacts the TFTs directly, Schottky junction may happen on the contacted surface of the source/drain electrode layer and the oxide semiconductor film, which may affect the conductive performance of the TFTs.

### SUMMARY OF THE INVENTION

The technical issue that the embodiment of the present disclosure solves is to provide a TFT manufacturing method to avoid the Schottky junction formed on the contacted surface of the source/drain electrode layer and the oxide semiconductor film so as to ensure the performance of the TFTs.

In one aspect, a manufacturing method of thin film transistors (TFTs) includes: providing a substrate; forming a first metallic layer on the substrate, and applying a patterning process to the first metallic layer such that the first metallic layer includes a pattern having a gate; forming a gate insulation layer on the substrate and the first metallic layer, the gate insulation layer covers a surface of the substrate and the gate; forming an oxide conductor layer orthogonally projecting on the gate insulation layer, wherein the oxide conductor layer is formed by physical vapor deposition (PVD); forming a second metallic layer on the substrate having the gate insulation layer formed thereon, patterning the second metallic layer to form a source and a drain of the TFT, wherein the source and the drain cover a portion of the oxide conductor layer; applying an ion surface treatment to the oxide conductor layer, which is not covered by the source and the drain and is arranged between the source and the drain, to form a first oxide trench layer on the oxide conductor layer, which is not covered by the source and the drain; and forming an insulation protection layer on the substrate and the patterned second metallic layer, and applying the patterning process to the insulation protection layer.

Wherein the ion surface treatment adopts a mixture of argon and oxygen.

Wherein the oxide conductor layer is made by IGZO, ZnO, InZnO, or ZnSNO having an oxygen content of a range between 0 and 20%.

Wherein before the step of forming the oxide conductor layer orthogonally projecting on the gate insulation layer, the method further includes: forming a second oxide trench layer on the gate insulation layer, the second oxide trench layer orthogonally projects on the gate and is between the gate and the oxide conductor layer, and the second oxide trench layer orthogonally projects on the oxide conductor layer.

Wherein the second oxide trench layer is made by IGZO, ZnO, InZnO, or ZnSnO having the oxygen content in the range between 4 and 50%.

Wherein the method further includes: forming an insulation protection layer on the patterned second metallic layer and the substrate, and applying the patterning process to the insulation protection layer.

Wherein the gate insulation layer and the insulation protection layer are made by one of SiOx, SiNx, and SiNxOy.

In another aspect, a TFT includes: a gate; an gate insulation layer covering the gate; an oxide layer covering the gate insulation layer and is above the gate, the oxide conductor layer includes an oxide trench layer and an oxide conductor layer at two opposite sides of the oxide trench layer; and a source and a drain arranged on the gate insulation layer and at two opposite sides of the oxide trench layer, and the source and the drain are electrically insulated from each other.

In another aspect, a TFT includes: a gate; an gate insulation layer covering the gate; a second oxide trench layer covering the gate insulation layer and is above the gate; an oxide layer covering the second oxide trench layer, and the oxide layer includes a first oxide trench layer and an oxide conductor layer at two opposite sides of the oxide trench layer; and a source and a drain arranged on the gate insulation layer and at two opposite sides of the oxide trench layer, and the source and the drain are electrically insulated from each other.

In another aspect, a display device includes the above TFT.

In view of the above, the oxide conductor layer having low oxygen content is formed on the gate insulation layer, and the oxide conductor layer contacts with the source and the drain, which ensures good electrical contact between the source/drain and the oxide conductor layer. By applying the ion surface treatment to form the first oxide trench layer having high oxygen content within the uncovered oxide conductor layer between the source and the drain, i.e., the oxide conductor layer, the good conductive performance of the TFTs may be provided.

### BRIEF DESCRIPTION OF THE DRAWINGS

In order to more clearly illustrate the embodiments of the present disclosure or prior art, the following figures will be described in the embodiments are briefly introduced. It is obvious that the drawings are merely some embodiments of the present disclosure, those of ordinary skill in this field can obtain other figures according to these figures without paying the premise.

FIG. 1 is a flowchart of the TFT manufacturing method in accordance with one embodiment.

FIGS. 2-8 are cross-sectional views of the TFTs in each of the manufacturing processes in accordance with one embodiment.

FIG. 9 is a flowchart of the TFT manufacturing method in accordance with another embodiment.

FIG. 10 is a cross-sectional view of the TFT formed by the manufacturing method of FIG. 9.

### DETAILED DESCRIPTION OF PREFERRED EMBODIMENTS

Embodiments of the present disclosure are described in detail with the technical matters, structural features, achieved objects, and effects with reference to the accompanying drawings as follows. It is clear that the described embodiments are part of embodiments of the present disclosure, but not all embodiments. Based on the embodiments of the present disclosure, all other embodiments to those of ordinary skill in the premise of no creative efforts obtained, should be considered within the scope of protection of the present disclosure.

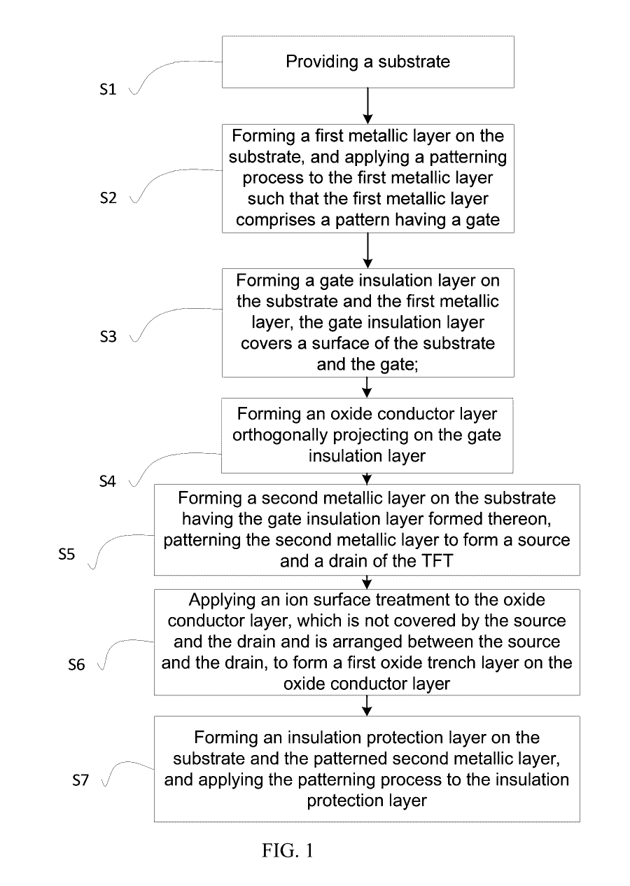

FIG. 1 is a flowchart of the TFT manufacturing method in accordance with one embodiment. The TFTs relate to oxide semiconductor TFTs. It is to be noted that patterning process relates to the lithographic process or/and the etching process. The patterning process may also include print, ink-jet and other processes for forming a predetermined pattern. The lithographic process relates to film formation, exposure, development, and other processes using a photoresist, the mask, an exposure machine. The corresponding patterning processes may be selected to form the structure of the present disclosure.

The TFT manufacturing method includes the following steps.

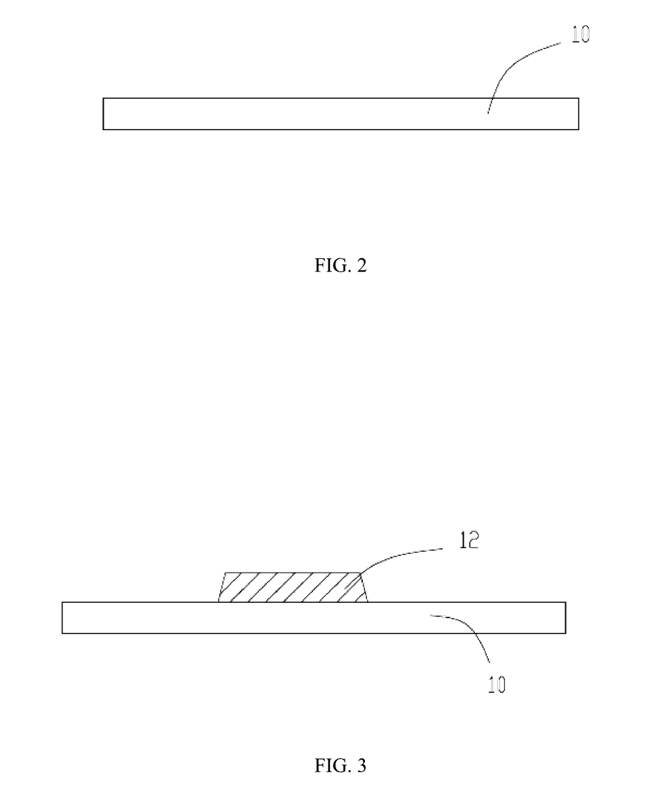

In step S1, a substrate 10 is provided. Also referring to FIG. 2, the substrate 10 is a glass substrate. It can be understood that the substrate 10 is not limited to the glass substrate.

Also referring to FIG. 3, in step S2, a first metallic layer (not shown) is formed on the substrate 10. By adopting the patterning process, the first metallic layer is formed on the substrate 10. The patterning process forms the first metallic layer having the pattern of the gate 12. Specifically, the first metallic layer is formed on the surface of the substrate 10 so as to be the gate 12 of the substrate 10. The first metallic layer may be made by one of the cooper, tungsten, chromium, aluminum, and the combination of the above. In one embodiment, the patterning process, including coating the photoresist, exposure, and lithography, is adopted to pattern the first metallic layer so as to form the gate 12.

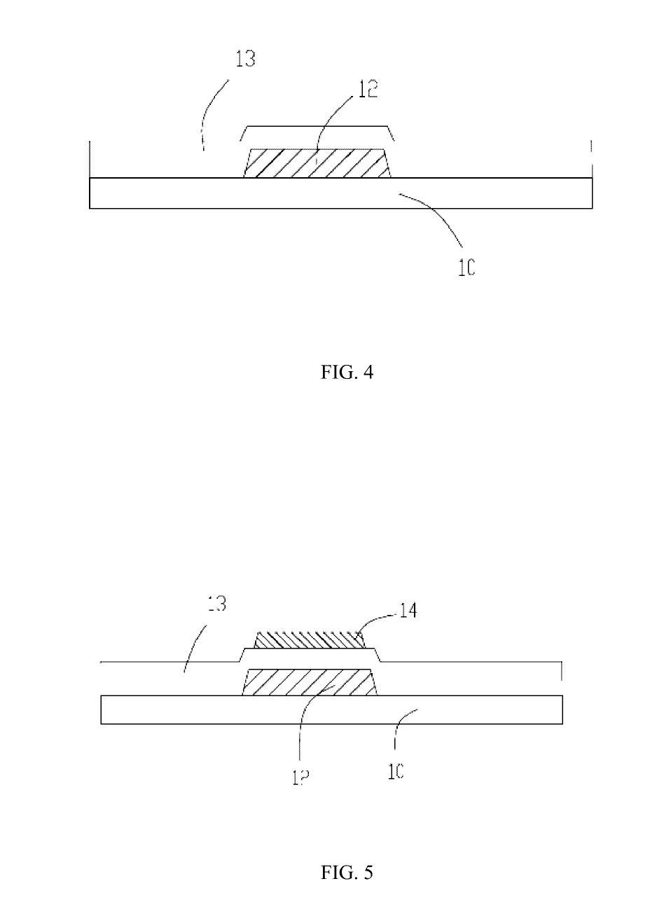

Referring to FIG. 4, in step S3, a gate insulation layer 13 is formed on the substrate 10 and on the patterned first metallic layer. The gate insulation layer 13 covers the surface of the substrate 10 and the gate. Specifically, the common electrode 130 is formed on the surface of the substrate that is not covered by the first metallic layer and the gate 12. The gate insulation layer 13 may be made by SiOx, silicon nitride layer, silicon oxynitride layer, and the combination of the above.

Referring to FIG. 5, in step S4, an oxide conductor layer 14 orthogonally projecting on the gate 12 is formed on the gate insulation layer 13. The oxide conductor layer 14 is formed by physical vapor deposition (PVD). In the embodiment, the oxide conductor layer 14 may be made by IGZO, ZnO, InZnO, or ZnSNO having an oxygen content of a range between 0 and 20%. Preferably, the oxide conductor layer 14 may be made by IGZO having the oxygen content of the range between 0 and 10%.

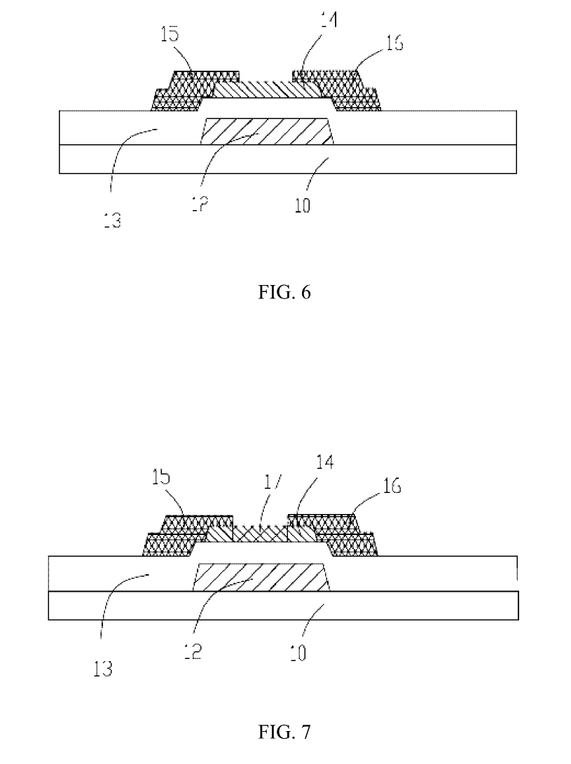

Referring to FIG. 6, in step S5, a second metallic layer (not shown) is formed on the substrate having the gate insulation layer 13 formed thereon. The second metallic layer is patterned to form a source 15 and a drain 16 of the TFT, wherein the source 15 and the drain 16 cover a portion of the oxide conductor layer 14.

Specifically, the second metallic layer, the oxide conductor layer 14, and the gate insulation layer 13 are stacked in sequence. The conventional patterning processes may be adopted to pattern the second metallic layer to form the source 15 and the drain 16. The second metallic layer may be made by one of the cooper, tungsten, chromium, aluminum, and the combination of the above.

Referring to FIG. 7, in step S6, an ion surface treatment is applied to the oxide conductor layer 14 that is not covered by the source 15 and the drain 16 and is arranged between the source 15 and the drain 16. As such, a first oxide trench layer 17 is formed on the oxide conductor layer 14 that is not covered by the source 15 and the drain 16.

By applying the ion surface treatment, a trench is formed within the oxide conductor layer 14 for connecting or disconnecting the source 15 and the drain 16. The ion surface treatment may adopt a mixture of argon and oxygen to apply an oxygen restoration toward the oxide conductor layer 14 that is not covered by the source 15 and the drain 16 and is arranged between the source 15 and the drain 16. In this way, the oxide semiconductor having the high oxygen content is formed, i.e., the first oxide trench layer 17. In one embodiment, the first oxide trench layer 17 is configured for connecting or disconnecting the source 15 and the drain 16. The oxide conductor layer 14 of the two sides of the first oxide trench layer 17 respectively contacting with the source 15 and the drain 16 operates as an ohmic contact layer.

The source 15 and the drain 16 may respectively form a good ohmic contact with the oxide conductor layer 14 below and the first oxide trench layer 17. The ohmic contact includes low resistance such that the source 15 may be of good conductive performance for the drain 16 via the first oxide trench layer 17.

In the embodiment, the second metallic layer may be metallic materials, but is not limited thereto. In other embodiments, the second metallic layer may be made by other conductive materials, such as alloy, nitride of metallic materials, nitrogen oxide of metallic materials, or a stacked layer composing of metallic materials and other conductive materials.

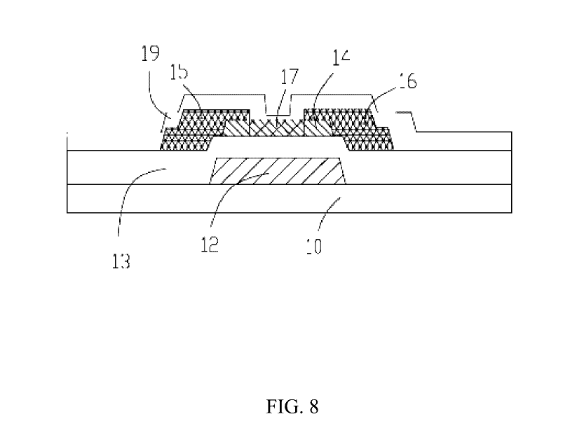

Referring to FIG. 8, in step S7, an insulation protection layer 19 is formed on the patterned second metallic layer (the source 15 and the drain 16) and the substrate 10. The patterning process is applied to the insulation protection layer 19. The gate insulation layer 13 and the insulation protection layer 19 may be made by one of SiOx, SiNx, and SiNxOy. The manufacturing method includes the above steps.

Further, the gate insulation layer 13 and the substrate 10 may be made by one of SiOx, SiNx, and SiNxOy.

The TFT manufacturing method includes forming the oxide conductor layer 14 having low oxygen content on the gate insulation layer 13, and the oxide conductor layer 14 contact with the source 15 and the drain 16 so as to provide a better electrical contact between the source 15, the drain 16, and the oxide conductor layer 14. By applying the ion surface treatment, the first oxide trench layer 17 having high oxygen content is formed within the uncovered oxide conductor layer 14 between the source 15 and the drain 16. As such, the conductive performance of the TFTs may be provided.

In view of the above, the TFT includes the gate, the gate insulation layer covering the gate, and the oxide layer covers the gate insulation layer and is arranged above the gate. The oxide layer includes the oxide trench layer and the oxide conductor layer at two sides of the first oxide trench layer, and a source and a drain formed on the gate insulation layer and the oxide conductor layer at two opposite sides of the first oxide trench layer. The source and the drain are electrically insulated from each other.

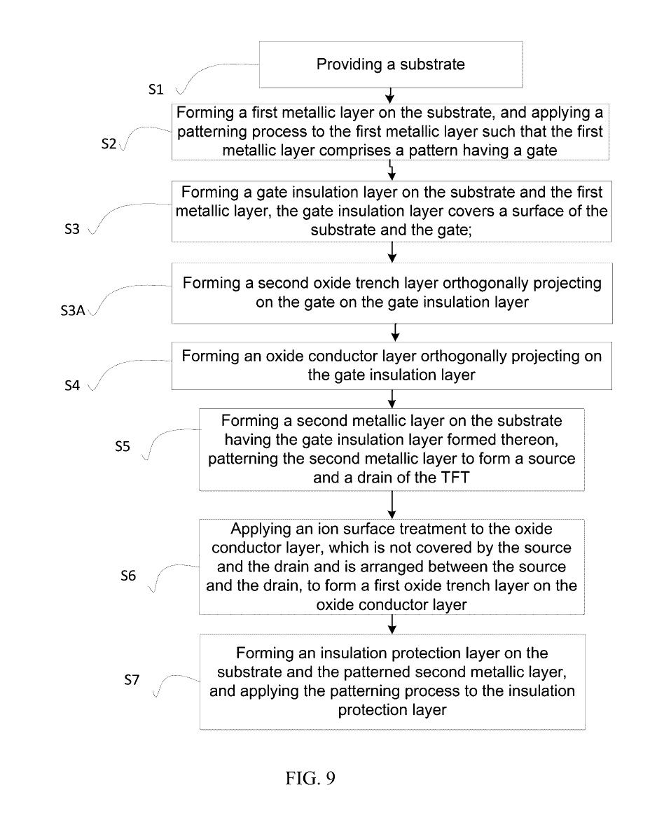

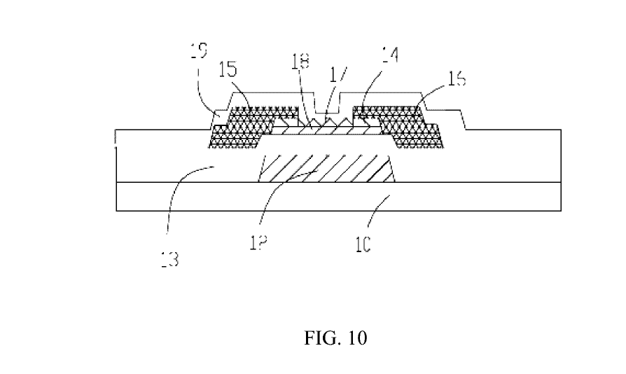

FIG. 9 is a flowchart of the TFT manufacturing method in accordance with another embodiment. The difference between this embodiment and the above embodiment will be described hereinafter.

Between step S3 and S4, the manufacturing method further includes a step S3A, wherein the second oxide trench layer 18 orthogonally projecting on the gate 12 is formed on the gate insulation layer 13. The second oxide trench layer 18 is between the gate 12 and the oxide conductor layer 14. In addition, the second oxide trench layer 18 orthogonally projects on the oxide conductor layer 14. The source 15 and the drain 16 contacts at least a portion of the oxide conductor layer 14 at two lateral sides of the first oxide trench layer 17. The first oxide trench layer 17 and the second oxide trench layer 18 cooperatively form the trench of the TFT.

The second oxide trench layer 18 may be made by IGZO, ZnO, InZnO, or ZnSnO having the oxygen content in the range between 4 and 50%. In the embodiment, the second oxide trench layer 18 may be made by IGZO having the oxygen content in the range between 5 and 200%.

FIG. 10 is a cross-sectional view of the TFT formed by the manufacturing method of FIG. 9. The TFT includes the gate, the gate insulation layer covering the gate, the second oxide trench layer covering the gate insulation layer and is above the gate, the oxide layer covering the gate insulation layer and is above the gate, and the source and the drain. The oxide layer includes the first oxide trench layer and the oxide conductor layer at two opposite sides of the first oxide trench layer. The source and the drain are arranged on the gate insulation layer and the oxide conductor layer on two opposite sides of the first oxide trench layer 17. The source and the drain are electrically insulated from each other.

In one embodiment, the display device includes the TFTs manufactured by the above two manufacturing methods. The display device may be a liquid crystal panel, LCD-TV, LCD, OLED panel, OLED TV, E-paper, digital photo frame, and cellular phones.

Above are embodiments of the present disclosure, which does not limit the scope of the present disclosure. Any modifications, equivalent replacements or improvements within the spirit and principles of the embodiment described above should be covered by the protected scope of the disclosure.

1. A manufacturing method of thin film transistors (TFTs), comprising:
providing a substrate;
forming a first metallic layer on the substrate, and applying a patterning process to the first metallic layer such that the first metallic layer comprises a pattern having a gate;
forming a gate insulation layer on the substrate and the first metallic layer, the gate insulation layer covers a surface of the substrate and the gate;
forming an oxide conductor layer orthogonally projecting on the gate insulation layer, wherein the oxide conductor layer is formed by physical vapor deposition (PVD);
forming a second metallic layer on the substrate having the gate insulation layer formed thereon, patterning the second metallic layer to form a source and a drain of the TFT, wherein the source and the drain cover a portion of the oxide conductor layer;
applying an ion surface treatment to the oxide conductor layer, which is not covered by the source and the drain and is arranged between the source and the drain, to form a first oxide trench layer on the oxide conductor layer, which is not covered by the source and the drain; and
forming an insulation protection layer on the substrate and the patterned second metallic layer, and applying the patterning process to the insulation protection layer.

2. The manufacturing method as claimed in claim 1, wherein the ion surface treatment adopts a mixture of argon and oxygen.

3. The method as claimed in claim 2, wherein the oxide conductor layer is made by IGZO, ZnO, InZnO, or ZnSNO having an oxygen content of a range between 0 and 20%.

4. The method as claimed in claim 1, wherein before the step of forming the oxide conductor layer orthogonally projecting on the gate insulation layer, the method further comprises:
forming a second oxide trench layer on the gate insulation layer, the second oxide trench layer orthogonally projects on the gate and is between the gate and the oxide conductor layer, and the second oxide trench layer orthogonally projects on the oxide conductor layer.

5. The method as claimed in claim 4, wherein the second oxide trench layer is made by IGZO, ZnO, InZnO, or ZnSnO having the oxygen content in the range between 4 and 50%.

6. The method as claimed in claim 1, wherein the method further comprises:
forming an insulation protection layer on the patterned second metallic layer and the substrate, and applying the patterning process to the insulation protection layer.

7. The method as claimed in claim 6, wherein the gate insulation layer and the insulation protection layer are made by one of SiOx, SiNx, and SiNxOy.

8. A TFT, comprising:
a gate;
an gate insulation layer covering the gate;
an oxide layer covering the gate insulation layer and is above the gate, the oxide conductor layer comprises an oxide trench layer and an oxide conductor layer at two opposite sides of the oxide trench layer; and
a source and a drain arranged on the gate insulation layer and at two opposite sides of the oxide trench layer, and the source and the drain are electrically insulated from each other.

9. A TFT, comprising:
a gate;
an gate insulation layer covering the gate;
a second oxide trench layer covering the gate insulation layer and is above the gate;
an oxide layer covering the second oxide trench layer, and the oxide layer comprises a first oxide trench layer and an oxide conductor layer at two opposite sides of the oxide trench layer; and
a source and a drain arranged on the gate insulation layer and at two opposite sides of the oxide trench layer, and the source and the drain are electrically insulated from each other.

10. A display device comprises the TFT as claimed in claim 8 or 9.

11. A display device comprises the TFT as claimed in claim 8.
